(19) United States
(12) Patent Application Publication
(10) Pub. No.: US 2016/0047851 A1
(43) Pub. Date: Feb. 18, 2016

(54) COMPUTER-AIDED ASCERTAINMENT OF THE IMPEDANCE OF AN ELECTRICAL ENERGY NETWORK

(71) Applicant: SIEMENS AKTIENGESELLCHAFT, München (DE)

(72) Inventors: Björn Andresen, Ostbirk (DK); Nikolaus Goldenbaum, Silkeborg (DK); Dragan Obradovic, Ottobrunn (DE); Andrei Szabo, Ottobrunn (DE)

(21) Appl. No.: 14/778,669

(22) PCT Filed: Mar. 28, 2013
(86) PCT No.: PCT/EP2013/056768

§ 371 Date: Sep. 21, 2015

(51) Int. Cl. G01R 27/16

(52) U.S. Cl. CPC G01R 27/16

(57) ABSTRACT

The embodiments relate to a method for the computer-aided ascertainment of the impedance of an electrical energy network, wherein the electrical voltage, the active power, and the reactive power are measured at a connection point, by which an electrical energy production installation is connected to the energy network, at respective successive instants. In this case, the impedance value is estimated at respective present instants by a computation code that is independent of the phase of the measured voltage. The estimation is carried out only for relatively large variations in the measured voltage or reactive power. The estimate is also taken into account only if its estimate error is small. The embodiments are based on the insight that accurate estimation of the impedance is possible at particular operating points of the energy network even without knowledge of voltage phase.

### CROSS-REFERENCE TO RELATED APPLICATIONS

The present patent document is a §371 nationalization of PCT Application Serial Number PCT/EP2013/056768, filed Mar. 28, 2013, designating the United States, which is hereby incorporated by reference.

### TECHNICAL FIELD

The embodiments relate to a method for computer-aided ascertainment of the impedance of an electrical power supply system and to an electrical power generating installation and a computer program product.

### BACKGROUND

The suitable control of a power generating installation connected to a power supply system at a connection point may require the impedance of the power supply system as a parameter. Various methods are known for estimating this impedance. One method involves the electrical components of the power supply system being modeled with the aid of a computer and this modeling being used to compute properties of the system and particularly the impedance thereof at the connection point. Such methods, however, are complex and require continuous updates in the event of modifications to the power supply system. In addition, it is known practice to determine properties of the power supply system by actively changing parameters of the power generating installation, but this has the disadvantage that normal operation of the installation is disrupted.

### SUMMARY AND DESCRIPTION

The scope of the present invention is defined solely by the appended claims and is not affected to any degree by the statements within this summary. The present embodiments may obviate one or more of the drawbacks or limitations in the related art.

It is an object of the embodiments to determine the impedance of an electrical power supply system in a simple manner using a computer-aided method.

The method is used for computer-aided ascertainment of the impedance of an electrical power supply system or power grid, wherein, at a connection point at which a power generating installation is connected to the power supply system, the electrical voltage, the active power, and the reactive power are measured at respective successive instants. Here and subsequently, a measured voltage refers to a real voltage value (e.g., voltage amplitude), such that the phase of the measured voltage is not determined. In the method, an impedance value for the power supply system is ascertained on the basis of acts a) to d) described below. In these acts, appropriate conditions are specified by the wording “only if”. This is intended to be understood to mean that only if the condition obtains is the relevant act performed, and otherwise the ascertainment of the impedance value at the relevant (present) instant is terminated.

Act a) of the method involves ascertaining, at a respective present instant, whether the absolute-value change in the measured voltage between the preceding and present instants and the absolute-value change in the measured reactive power between the preceding and present instants satisfy a first criterion. The first criterion is satisfied when the absolute-value change in the measured voltage is greater than a first threshold value and the absolute-value change in the measured reactive power is greater than a second threshold value.

Act b) involves, only if the absolute-value changes in the measured voltage and the measured reactive power satisfy the first criterion, ascertaining whether the changes in the measured voltage and the measured reactive power satisfy a second criterion, wherein the second criterion is satisfied when the changes in the measured voltage and the measured reactive power are caused by the power generating installation. Here and subsequently, the term change without the supplement “absolute-value” refers to a signed, non-absolute-value change.

Act c) involves, only if the changes in the measured voltage and the measured reactive power satisfy the second criterion, estimating an impedance value on the basis of a computation rule, which is independent of the phase of the measured voltage. In particular, the computation rule is embodied such that it is valid for a constant phase of the measured voltage. This act also involves determining an estimation error for the estimated impedance value. The estimated impedance value represents the ascertained impedance value only if the estimation error is below a predetermined error threshold, e.g., only in this case is the impedance value updated by the estimated impedance value.

The method is based on the insight that, in an inductive power supply system (e.g., a power supply system having a small or no real part for the impedance), to which power generating installations may be connected, operating points arise at which a simple computation rule may be used to accurately determine the impedance without considering the phase of the measured voltages. In this case, it has been identified that the computation rule may be used with sufficient accuracy only when a larger variation in the voltage and reactive power measured at the connection point occurs and at the same time the variation in the active power is small, the latter condition being checked indirectly via the estimation error.

In a particular embodiment, in act b) the second criterion is checked in a simple manner such that the arithmetic sign of the change in the measured voltage is compared with the arithmetic sign of the change in the measured reactive power, wherein the second criterion is satisfied when the two arithmetic signs match.

In a further variant of the method, the predetermined error threshold from act d) is the estimation error that has been ascertained in act d) performed most recently before the present instant. This provides that the impedance value is only ever updated when its estimation error becomes smaller.

The first and second threshold values defined above may be stipulated by considering a (e.g., previously ascertained) percentage measurement accuracy, so that there is the assurance that the changes are not caused by measurement errors. In this case, the first threshold value is a product of a positive factor greater than one and a percentage measurement accuracy for the measured voltage and/or the second threshold value is the product of a positive factor greater than one and a percentage measurement accuracy for the measured power. Particularly, the value 5 has been found to be feasible as a positive factor.

In a further variant, the change in the active power between the preceding and present instants is ascertained, wherein the ascertainment of the impedance value at the present instant is terminated if the absolute-value change in the active power is greater than a third threshold value. This takes account of the insight that accurate estimation of the impedance is possible only for a small variation in the active power.

In a further embodiment of the method, in which the change in the active power between the preceding and present instants is also ascertained, the estimation error in act c) is determined on the basis of a predetermined relation. This relation indicates the estimation error on the basis of the measured active power, the absolute-value change in the measured active power, and the absolute-value change in the measured reactive power. In this case, the ascertainment of the relation may be produced for an exemplary power supply system by comparing impedance values estimated using the above computation rule with the impedance values that actually occur. For the purpose of determining the actual impedance value, the power supply system may be simulated using methods that are known per se or may be a real power supply system. The relation may be stored in the form of one or more tables, for example. The detailed description contains a graphical representation of a relation by way of example.

In a further variant of the method, the impedance value is estimated in act c) using the measured voltages, the measured active powers and the measured reactive powers to produce a number of instants including the present instant and one or more preceding instants on the basis of one or more of the following equations, these equations being a variant of the computation rule from act c):

$${Z}_{GE} = \frac{{U}_{2} - {U}_{1}}{( \frac{{P}_{2}}{{U}_{2}} - \frac{{P}_{1}}{{U}_{1}} ) - ( \frac{j {Q}_{2}}{{U}_{2}} - \frac{j {Q}_{1}}{{U}_{1}} )}$$

where Z_{GE} is the estimated impedance value;

where U₂ is the measured voltage, Q₂ is the measured reactive power, and P₂ is the measured active power at the connection point at an instant from the number of instants; and

where U₁ and Q₁ and P₁ are the measured voltage and the measured reactive power and the measured active power, respectively, at the connection point at the instant before the instant at which the voltage U₂, the reactive power Q₂, and the active power P₂ are measured.

The above equation system may be resolved on the basis of minimization of the mean square error. In a simple variant, the equation system includes only one equation, provided that only values at the present and preceding instants are considered.

In a further variant, if the period of time since the last instant at which act d) was performed exceeds a predetermined threshold, one or more parameters of the power generating installation are varied such that the voltage and/or the reactive power at the connection point are changed. In this case, the variation in the parameters initiates the performance of the above acts a) to d) of the method. This achieves the effect that active excitation of the power generating installation changes operating parameters, which may result in re-estimation of the impedance value. The variation in the parameters of the power generating installation may be embodied in this case such that the active power at the connection point remains constant. This takes account of the estimation error described above becoming small when the active power is constant, resulting in a redetermination of the impedance value.

In a further embodiment, if the absolute-value change in the measured voltage is greater than a fourth threshold value, which is greater than the first threshold value, and/or the absolute-value change in the measured reactive power is greater than a fifth threshold value, which is greater than the second threshold value, and the absolute-value changes in the measured voltage and the measured reactive power do not satisfy the second criterion, one or more parameters of the power generating installation are varied such that the voltage and/or the reactive power at the connection point are changed. In this case, the variation in the parameters initiates the performance of the above acts a) to d) of the method. This allows for the fact that larger events in the power supply system prompt the impedance of the system to be changed, so that recomputation of the impedance may be initiated. In this case, the variation in the parameters of the power generating installation may be embodied such that the active power at the connection point remains constant, so that the variation also actually results in redetermination of the impedance.

In one variant, the method is used in a power supply system to which a power generating installation in the form of a wind turbine or a wind farm including a plurality of wind turbines is connected. Notwithstanding, the method may if need be also be used for other power generating installations.

Besides the method described above, the embodiments additionally relate to an electrical power generating installation, wherein the power generating installation is embodied such that, when connected to a connection point of a power supply system, it performs the method or one or more variants of the method. The ascertained impedance values may then be processed directly by relevant control units in the power generating installation in order to match the operation of the power generating installation to the power supply system in a suitable fashion.

The embodiments furthermore relate to a computer program product having a program code, stored on a machine-readable storage medium, for performing the method or one or more variants of the method when the program code is executed on a computer.

### BRIEF DESCRIPTION OF THE DRAWINGS

Exemplary embodiments are described in detail below with reference to the appended figures, in which:

FIG. 1 depicts a schematic illustration of a three-phase power supply system with a connection point for a power generating installation, in which power supply system an embodiment of the method is performed.

FIG. 2 depicts the modeling of the impedance of the three-phase power supply system of FIG. 1 by a single-phase phase system.

FIG. 3 depicts a schematic illustration that clarifies the acts of an embodiment of the method.

FIG. 4 depicts an example of a graphical representation of a relation for determining an estimation error for the impedance estimated.

### DETAILED DESCRIPTION

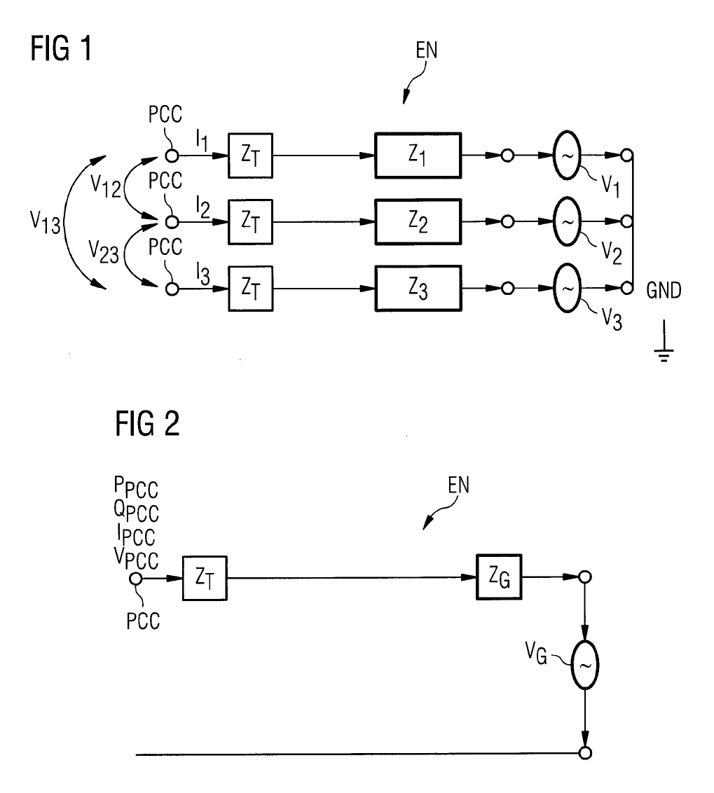

The embodiment of the method below is described on the basis of a three-phase power supply system, which is depicted as a Thevenin equivalent in FIG. 1. The impedance in the individual phases 1, 2, and 3 of the power supply system is denoted by Z₁, Z₂, and Z₃. The corresponding voltages in the power grid are denoted by V₁, V₂, and V₃. The power supply system has a power generating installation connected to it via the point of common coupling (PCC), the connection point being reproduced again separately for the three phases. The current that is present in the phases is denoted by I₁, I₂, and I₃. In addition, a transformer is present for the individual phases, the impedance of the transformer being denoted by Z_{T}. This impedance is subsequently included in the respective impedances Z₁, Z₂, and Z₃. The voltages between the individual phases are denoted by V₁₂, V₁₃, and V₂₃ in FIG. 1.

For the embodiment described here, a balanced three-phase power supply system having the same impedances Z₁ to Z₃ and the same voltages V₁ to V₃ (e.g., with a 120 degree phase difference) is assumed. Accordingly, the impedances may be ascertained on the basis of a single-phase system that is depicted in FIG. 2. In the single-phase system depicted in FIG. 2, V_{G} represents the value of the identical voltages V₁ to V₃ from FIG. 1 and Z_{G} corresponds to the value of the identical impedances Z₁ to Z₃ from FIG. 1. The voltage V_{PCC} and the current I_{PCC} at the connection point PCC correspond to the voltage and the current of a phase. The voltage V_{PCC} is measured by the connected power generating installation. Similarly, the current I_{PCC} and also the reactive power Q_{PCC} and the active power P_{PCC} are ascertained by the power generating installation. By analogy with FIG. 1, the impedance Z_{T} of the transformer is again included in the impedance Z_{G} of the power supply system.

The aim of the embodiment of the method that is described below is now to take the measured values V_{PCC}, Q_{PCC}, and P_{PCC} as a basis for correctly determining the impedance of the power supply system. In theory, the impedance Z_{G} may be ascertained in a manner known per se using the following formula:

$${Z}_{G} = \frac{{U}_{2} - {U}_{1}}{{I}_{2} - {I}_{1}}$$

In this case, U₂ and I₂ are the complex-value voltages and currents at one instant at the connection point, and U₁ and I₁ are the corresponding complex-value voltages and currents at another instant at the connection point. The above voltages and currents therefore contain a phase value. In this case, determination of these phase values proves problematic owing to frequency fluctuations in the power supply system. So as nevertheless to ascertain a correct impedance value Z_{G}, a computation rule is used below that determines the impedance value assuming a constant phase for the voltage at the connection point. This makes use of the insight that, during operation of the power grid, operating points repeatedly occur at which estimation of the impedance using this computation rule results in small estimation errors. Analyzing the estimation error may then be used to define when a corresponding estimation of the impedance is classified as valid.

In particular, it has been identified that the use of a computation rule that assumes a constant phase for the measured voltage leads to small estimation errors whenever a change in the measured voltage and reactive power at the connection point occurs with simultaneously low variation in the active power and the power supply system is reactive, e.g., when the real part of the impedance of the power supply system is small. The latter assumption may be fulfilled when a power generating installation is connected to a high-voltage power supply system.

The computation rule used for estimating the impedance is the following equation system, which has already been mentioned above:

$${Z}_{GE} = \frac{{U}_{2} - {U}_{1}}{( \frac{{P}_{2}}{{U}_{2}} - \frac{{P}_{1}}{{U}_{1}} ) - ( \frac{j {Q}_{2}}{{U}_{2}} - \frac{j {Q}_{1}}{{U}_{1}} )}$$

where Z_{GE} is the estimated impedance value;

where U₂ is the measured voltage, Q₂ is the measured reactive power, and P₂ is the measured active power at the connection point at an instant from a number of instants including the present instant and one or more preceding instants; and

where U₁ and Q₁ and P₁ are the measured voltage and the measured reactive power and the measured active power, respectively, at the connection point at the instant before the instant at which the voltage U₂, the reactive power Q₂, and the active power P₂ are measured.

In one variant, only the present instant and the immediately preceding instant are considered in this case, which provides that the equation system includes only one equation. In this case, U₂, Q₂, and P₂ relate to the present instant and U₁, Q₁, and P₁ relate to the immediately preceding instant.

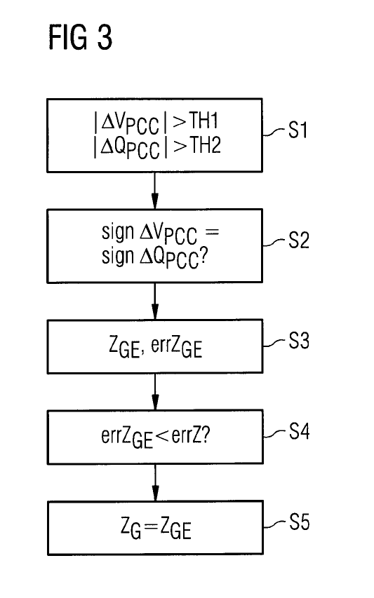

Acts of the method are explained below with reference to FIG. 3. There, the method is performed in acts at appropriate present instants t, and FIG. 3 depicts the method acts at a corresponding instant t. At this instant, act S1 checks whether the absolute-value change |ΔV_{PCC}| in the voltage V_{PCC} at the connection point between the present and preceding instants is greater than a threshold value TH1 and whether the absolute-value change |ΔQ_{PCC}| in the reactive power Q_{PCC} at the connection point between the present and preceding instants is greater than a threshold value TH2. This uses the insight that a necessary prerequisite for small estimation errors when the aforementioned computation rule is used is that a variation in the voltage and reactive power at the connection point occurs. In one variant, the threshold values TH1 and TH2 are determined on the basis of a previously ascertained accuracy for the measurement of the voltage and the reactive power. In particular, the corresponding thresholds represent the product of a positive factor greater than one (e.g., 5) and a corresponding measurement accuracy as a percentage.

Only if the conditions according to act S1 are satisfied is the estimation of the impedance at the present instant continued, otherwise the estimation is terminated. If the conditions according to act S1 are satisfied, act S2 checks whether the corresponding changes in the voltage and reactive power at the connection point have been caused by the power generating installation or the power supply system. Only if the power generating installation causes the variation in the voltage and the reactive power is it possible to estimate the impedance. In the embodiment described here, act S2 checks whether the arithmetic sign of the change ΔV_{PCC} in the voltage V_{PCC} corresponds to the arithmetic sign of the change ΔQ_{PCC} in the reactive power Q_{PCC}. Only if the arithmetic signs match has the change in the voltage and the reactive power been initiated by the power generating installation. If this is the case, the method is continued in act S3. Otherwise, the estimation of the impedance at the present instant is terminated.

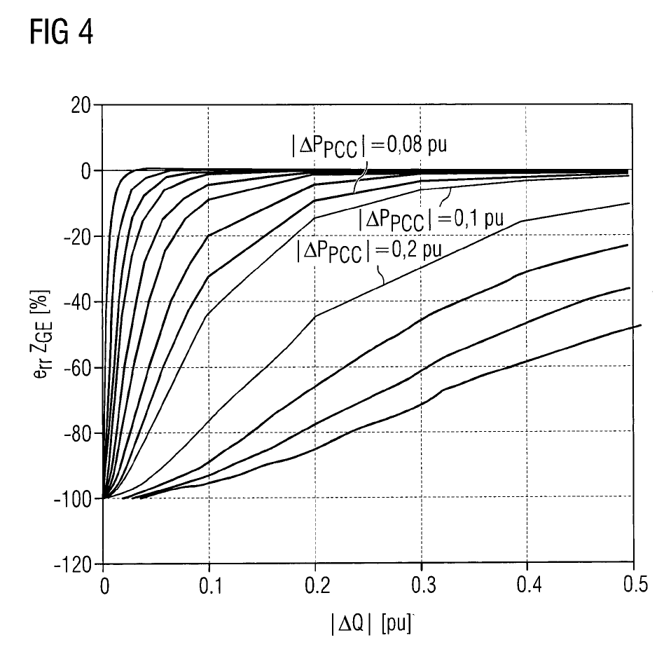

When the method is continued, act S3 then estimates the impedance value Z_{GE} on the basis of the above computation rule. In addition, an estimation error errZ_{GE} is ascertained for this estimation. In this case, the determination of the estimation error is based on a relation that has been determined beforehand for the simulation of a power supply system and possibly during real operation of the power supply system. FIG. 4 depicts a graph that describes this relation, by way of example. In this graph, corresponding power values are indicated in pu (per unit) and the estimation error is indicated as a percentage, without limiting generality. To determine the graph, Z_{G}=0.0707+0.4950j (in pu) has been taken as a basis as a value for the actual impedance for simulation of the power supply system. In the graph, the estimation error errZ_{GE} is indicated on the basis of the absolute-value variation |ΔQ_{PCC}| in the reactive power, the different lines in the graph being valid for different values of the absolute-value variation |ΔP_{PCC}| in the active power ΔP_{PCC}. FIG. 4 indicates, merely by way of example for three lines, the absolute-value variation in the active power for which the relevant line is valid. The absolute-value variation in the active power increases from left to right for the lines in this case.

The graph in FIG. 4 has been determined for a predetermined value of the active power at the present instant. For the purpose of determining the estimation error, there exists a multiplicity of the graphs depicted in FIG. 4, each graph having been ascertained for a different value of the active power by simulations. In order to determine the estimation error in act S3, the relevant graph that corresponds to the present value of the active power at the connection point is now selected. Next, the line that corresponds to the variation in the active power at the connection point is picked out. On the basis of this line, the estimation error is then read off for the absolute-value variation in the reactive power. As may be seen from the graph in FIG. 4, the estimation errors are small whenever the variation in the reactive power is large and the variation in the active power is small, e.g., the above computation rule is suitable for estimating Z_{GE} in that case.

Following determination of the estimation error, act S4 ascertains whether this estimation error is smaller than the estimation error errZ. In this case, the estimation error errZ is the estimation error determined most recently at an earlier instant. Only if the present estimation error errZ_{GE} is smaller than the most recently determined estimation error errZ does act S5 consider the estimated impedance value Z_{GE} to be a valid ascertained impedance value Z_{G}. If the condition from act S4 is not satisfied, the estimation of the impedance at the present instant is terminated. The impedance value determined in act S5 may then be processed in the power generating installation or appropriate control unit(s) in the power generating installation in a suitable fashion in order to match operation of the installation to the circumstances of the power supply system.

In a particular embodiment of the method described above, parameters of the power generating installation are additionally, under certain conditions, actively changed, with the change in the parameters influencing the voltage and reactive power at the connection point. In a variant, such a change is made when the period of time since the last instant at which act S5 was performed exceeds a predetermined threshold. The effect achieved by this is that new operating conditions are created when the present operating conditions have for a long time no longer resulted in suitable estimation of an impedance. The active excitation of the power generating installation may be embodied such that this involves the active power at the connection point remaining constant. In this case, it may be expected that conditions according to which estimation of the impedance is possible are again present.

In a further embodiment, a significant event in the power supply system likewise prompts the performance of active excitation of the power generating installation. A significant event is detected when the condition according to act S2 is not satisfied but the absolute-value change in the voltage and/or the absolute-value change in the reactive power is very large. In this regard, appropriate threshold values are defined for the absolute-value changes that are much greater than the threshold values TH1 and TH2. This variant takes into account that a significant event in the power supply system results in a change in the impedance thereof, so that it is necessary for the impedance value to be updated.

The embodiments of the method that are described above have a series of advantages. In particular, it is possible, during operation of a power generating installation, to ascertain good estimations of the impedance at the connection point of the installation on line with small active disruptions to the power supply system. In this case, the embodiments are based on the insight that, for particular operating points of the power generating installation or the power supply system, accurate estimation of an impedance is possible without considering the phase variation of the voltage at the connection point, which may not be determined accurately on account of frequency instabilities. The method may be used for any types of power generating installations, in one embodiment the power generating installation being a wind farm including a plurality of wind turbines.

The power supply system to which the power generating installation is connected is particularly a high-voltage power supply system for which the impedance is reactive and therefore has only a small or no real part.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method for computer-aided ascertainment of an impedance value of an electrical power supply system, wherein, at a connection point at which an electrical power generating installation is connected to the power supply system, an electrical voltage, an active power, and a reactive power are measured at respective successive instants, by the method of ascertaining the impedance value comprising:
a) ascertaining, at a respective present instant, whether an absolute-value change in the measured voltage between a preceding instant and the present instant and an absolute-value change in the measured reactive power between the preceding and present instants satisfy a first criterion, wherein the first criterion is satisfied when the absolute-value change in the measured voltage is greater than a first threshold value and the absolute-value change in the measured reactive power is greater than a second threshold value;
b) ascertaining whether the changes in the measured voltage and the measured reactive power satisfy a second criterion, when the absolute-value changes in the measured voltage and the measured reactive power satisfy the first criterion, wherein the second criterion is satisfied when the changes in the measured voltage and the measured reactive power are caused by the power generating installation;
c) estimating an impedance value based on a computation rule, which is independent of the phase of the measured voltage, and determining an estimation error for the estimated impedance value when the changes in the measured voltage and the measured reactive power satisfy the second criterion;
d) representing the ascertained impedance value with the estimated impedance value when the estimation error is below a predetermined error threshold.

2. The method as claimed in claim 1, wherein the second criterion is checked in act b) such that the arithmetic sign of the change in the measured voltage is compared with the arithmetic sign of the change in the measured reactive power, wherein the second criterion is satisfied when the two arithmetic signs match.

3. The method as claimed in claim 1, wherein the predetermined error threshold is the estimation error that has been ascertained in act d) performed most recently before the present instant.

4. The method as claimed in claim 1, wherein the first threshold value is a product of a positive factor greater than one and a percentage measurement accuracy for the measured voltage and/or the second threshold value is a product of a positive factor greater than one and a percentage measurement accuracy for the measured reactive power.

5. The method as claimed in claim 1, further comprising:
ascertaining the change in the active power between the preceding and present instants, wherein the ascertainment of the impedance value at the present instant is terminated when the absolute-value change in the active power is greater than a third threshold value.

6. The method as claimed in claim 1, further comprising:
ascertaining the change in the active power between the preceding and present instants, wherein the estimation error is determined in act c) based on a predetermined relation that indicates the estimation error based on the measured active power, the absolute-value change in the measured active power, and the absolute-value change in the measured reactive power.

7. The method as claimed in claim 1, wherein the impedance value is estimated in act c) using the measured voltages, the measured active powers, and the measured reactive powers to produce a number of instants comprising the present instant and one or more preceding instants based on:
$${Z}_{GE} = \frac{{U}_{2} - {U}_{1}}{( \frac{{P}_{2}}{{U}_{2}} - \frac{{P}_{1}}{{U}_{1}} ) - ( \frac{j {Q}_{2}}{{U}_{2}} - \frac{j {Q}_{1}}{{U}_{1}} )}$$
where wherein:
Z_{GE} is the estimated impedance value;
U₂ is the measured voltage, Q₂ is the measured reactive power, and P₂ is the measured active power at the connection point at an instant from the number of instants; and
U₁ and Q₁ and P₁ are the measured voltage and the measured reactive power and the measured active power, respectively, at the connection point at the instant before the instant at which the voltage U₂, the reactive power Q₂ and the active power P₂ are measured.

8. The method as claimed in claim 1, wherein when the period of time since the last instant at which act d) was performed exceeds a predetermined threshold, one or more parameters of the power generating installation are varied such that the voltage and/or the reactive power at the connection point are changed, wherein the variation in the parameters initiates the performance of acts a) to d).

9. The method as claimed in claim 1, wherein when the absolute-value change in the measured voltage is greater than a fourth threshold value, which is greater than the first threshold value, and/or the absolute-value change in the measured reactive power is greater than a fifth threshold value, which is greater than the second threshold value, and the absolute-value changes in the measured voltage and the measured reactive power do not satisfy the second criterion, one or more parameters of the power generating installation are varied such that the voltage, the reactive power, or the voltage and the reactive power at the connection point are changed, wherein the change in the parameters initiates the performance of acts a) to d).

10. The method as claimed in claim 1, wherein the power generating installation is a wind turbine or a wind farm comprising a plurality of wind turbines.

11. An electrical power generating installation, when connected to a connection point of a power supply system, is configured to:
ascertain, at a respective present instant, whether an absolute-value change in a measured voltage between a preceding instant and the present instant and an absolute-value change in a measured reactive power between the preceding and present instants satisfy a first criterion, wherein the first criterion is satisfied when the absolute-value change in the measured voltage is greater than a first threshold value and the absolute-value change in the measured reactive power is greater than a second threshold value;
ascertain whether the changes in the measured voltage and the measured reactive power satisfy a second criterion, when the absolute-value changes in the measured voltage and the measured reactive power satisfy the first criterion, wherein the second criterion is satisfied when the changes in the measured voltage and the measured reactive power are caused by power generating installation;
estimate an impedance value based on a computation rule, which is independent of the phase of the measured voltage, and determine an estimation error for the estimated impedance value when the changes in the measured voltage and the measured reactive power satisfy the second criterion;
represent the ascertained impedance value with the estimated impedance value when the estimation error is below a predetermined error threshold.

12. A computer program product having a program code, stored on a machine-readable storage medium of a computer, the computer program code configured to cause the computer to at least perform:
ascertain, at a respective present instant, whether an absolute-value change in a measured voltage between a preceding instant and the present instant and an absolute-value change in a measured reactive power between the preceding and present instants satisfy a first criterion, wherein the first criterion is satisfied when the absolute-value change in the measured voltage is greater than a first threshold value and the absolute-value change in the measured reactive power is greater than a second threshold value;
ascertain whether the changes in the measured voltage and the measured reactive power satisfy a second criterion, when the absolute-value changes in the measured voltage and the measured reactive power satisfy the first criterion, wherein the second criterion is satisfied when the changes in the measured voltage and the measured reactive power are caused by the power generating installation;
estimate an impedance value based on a computation rule, which is independent of the phase of the measured voltage, and determine an estimation error for the estimated impedance value when the changes in the measured voltage and the measured reactive power satisfy the second criterion;
represent the ascertained impedance value with the estimated impedance value when the estimation error is below a predetermined error threshold.

13. The method as claimed in claim 8, wherein the variation in the parameters is configured such that the active power at the connection point remains constant.

14. The method as claimed in claim 9, wherein the variation in the parameters is configured such that the active power at the connection point remains constant.

15. The method as claimed in claim 2, wherein the predetermined error threshold is the estimation error that has been ascertained in act d) performed most recently before the present instant.

16. The method as claimed in claim 15, wherein the first threshold value is a product of a positive factor greater than one and a percentage measurement accuracy for the measured voltage and/or the second threshold value is a product of a positive factor greater than one and a percentage measurement accuracy for the measured reactive power.

17. The method as claimed in claim 16, further comprising:
ascertaining the change in the active power between the preceding and present instants, wherein the ascertainment of the impedance value at the present instant is terminated when the absolute-value change in the active power is greater than a third threshold value.

18. The method as claimed in claim 16, further comprising:
ascertaining the change in the active power between the preceding and present instants, wherein the estimation error is determined in act c) based on a predetermined relation that indicates the estimation error based on the measured active power, the absolute-value change in the measured active power, and the absolute-value change in the measured reactive power.

19. The method as claimed in claim 2, wherein the first threshold value is a product of a positive factor greater than one and a percentage measurement accuracy for the measured voltage and/or the second threshold value is a product of a positive factor greater than one and a percentage measurement accuracy for the measured reactive power.
